(19) United States
(12) Patent Application Publication
(10) Pub. No.: US 2025/0246217 A1
(43) Pub. Date: Jul. 31, 2025

(54) MEMORY SYSTEM AND MEMORY DIE

(71) Applicant: NANYA TECHNOLOGY CORPORATION, New Taipei City (TW)

(72) Inventor: Wu-Der Yang, Taoyuan City (TW)

(73) Assignee: NANYA TECHNOLOGY CORPORATION, New Taipei City (TW)

(21) Appl. No.: 18/426,356

(22) Filed: Jan. 30, 2024

(51) Int. Cl. G11C 7/10; G06F 7/501; G11C 7/14

(52) U.S. Cl. CPC G11C 7/1063; G06F 7/501; G11C 7/14

(57) ABSTRACT

Memory systems and memory dies are provided. The memory system of the present disclosure includes a plurality of memory dies stacked within the memory system. Each memory die includes a numbering circuit configured to generate an output number signal according to an input number signal. The numbering circuit includes a plurality of calculating circuits coupled in series. A current stage calculating circuit is configured to receive a first output bit from a previous stage calculating circuit and a corresponding bit of the input number signal to generate the first output bit and a second output bit as a correspond bit of the output number signal.

### BACKGROUND

### 1. Technical Field

The disclosure generally relates to a system and a die, and more particularly, to a memory system and a memory die.

### 2. Description of Related Art

The three-dimensional integrated circuit (3DIC) have grown rapidly. In order to correctly access all dies stacked in the 3DIC, an identification number corresponding to a level where the die is in the stack may be programmed or set to each die through hardwires or e-fuses. However, these methodologies are required to be applied to each of the memory die they are stacked, or even during fabrication. In this way, a possibility that an error to occur in the 3DIC gets higher since each die is labeled with the identification number and must be placed on a corresponding level in the stack.

### SUMMARY

Accordingly, the present disclosure is directed to a memory system and a memory die capable of automatically and internally generating a number signal corresponding to the level where the memory die is in the 3DIC stack.

The memory system of the present disclosure includes a plurality of memory dies stacked within the memory system. Each memory die includes a numbering circuit configured to generate an output number signal according to an input number signal. The numbering circuit includes a plurality of calculating circuits coupled in series. A current stage calculating circuit is configured to receive a first output bit from a previous stage calculating circuit and a corresponding bit of the input number signal to generate the first output bit and a second output bit as a correspond bit of the output number signal.

The memory die of the present disclosure is adapted to be stacked within a memory system. The memory die includes a numbering circuit configured to generate an output number signal according to an input number signal. The numbering circuit includes a plurality of calculating circuits coupled in series. A current stage calculating circuit is configured to receive a first output bit from a previous stage calculating circuit and a corresponding bit of the input number signal to generate the first output bit and a second output bit as a correspond bit of the output number signal.

To make the aforementioned more comprehensible, several embodiments accompanied with drawings are described in detail as follows.

### BRIEF DESCRIPTION OF THE DRAWINGS

FIG. 1 illustrates a memory system 1 according to some embodiments of the present disclosure.

FIG. 2 illustrates a schematic diagram of a numbering circuit 10a according to some embodiments of the present disclosure.

FIG. 3A illustrates a schematic diagram of a calculating circuit 100b according to some embodiments of the present disclosure.

FIG. 3B illustrates a truth table T1 of a calculating circuit 100b in FIG. 3A according to some embodiments of the present disclosure.

FIG. 3C illustrates a numbering circuit 10b according to some embodiments of the present disclosure.

FIG. 3D illustrates a truth table T2 of a numbering circuit 10b in FIG. 3C according to some embodiments of the present disclosure,

FIG. 4 illustrates a plurality of serially coupled numbering circuits 10b-1 to 10b-4 according to some embodiments of the present disclosure.

### DESCRIPTION OF THE EMBODIMENTS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

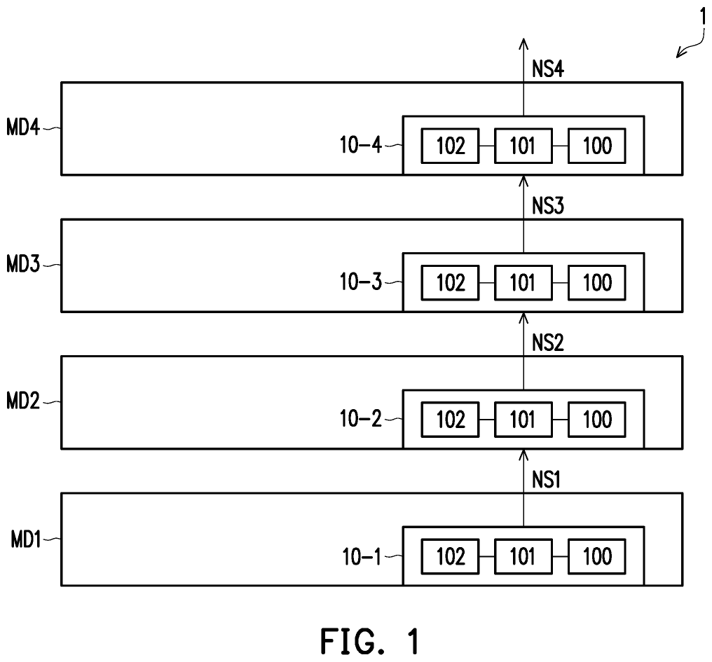

FIG. 1 illustrates a memory system 1 according to some embodiments of the present disclosure. The memory system 1 includes a plurality of memory dies MD1-MD4 stacking along a vertical direction within the memory system 1 serving as a three-dimensional integrated circuit (3DIC) system. Each memory die in the stack is coupled to an adjacent memory die on top or bottom level using through silicon vias (TSVs) for supports and/or data exchange. Each memory die includes a numbering circuit configured receive an input number signal from the number circuit of the adjacent memory die to generate an output number signal corresponding to a level where the memory die is in the stack, thereby automatically providing a location information for each memory die, so that the memory die may utilize the output number signal to determine whether or not to execute a received read/write signal. In some embodiments, the plurality of memory dies MD1-MD4 have the same structure, respectively utilizing the numbering circuit inside to generate the output number signal, so that a design complexity of the memory system 1 may be effectively reduced.

Specifically, the plurality of numbering circuits 10-1 to 10-4 respectively disposed in the memory dies MD1-MD4 are coupled in series. Each numbering circuit may be configured to receive the input number from the numbering circuit at a previous stage to generate the output number signal. Then, the generated output number signal may be provided to the numbering at a next stage as its input number signal. Taking the numbering circuit 10-2 in the memory die MD2 as an example, the numbering circuit 10-2 is configured to receive the input number signal NS1 from the numbering circuit 10-2 at the previous stage, and generate the output number signal NS2 accordingly. Further, each numbering circuit includes a plurality of calculating circuits coupled in series. A current stage calculating circuit is configured to receive a first output bit from a previous stage calculating circuit and a corresponding bit of the input number signal to generate the first output bit and a second output bit as a correspond bit of the output number signal. In this way, each numbering circuit may receive the input number signal from the neighboring numbering circuit at the previous stage to generate the output number signal through the serially coupled calculating circuits inside. In addition, the calculating circuits may be designed using the same circuit with a relatively simple circuit structure, thereby implementing the automatically numbering function through a simpler design, and improving a flexibility of processing the number signal of with different bit numbers.

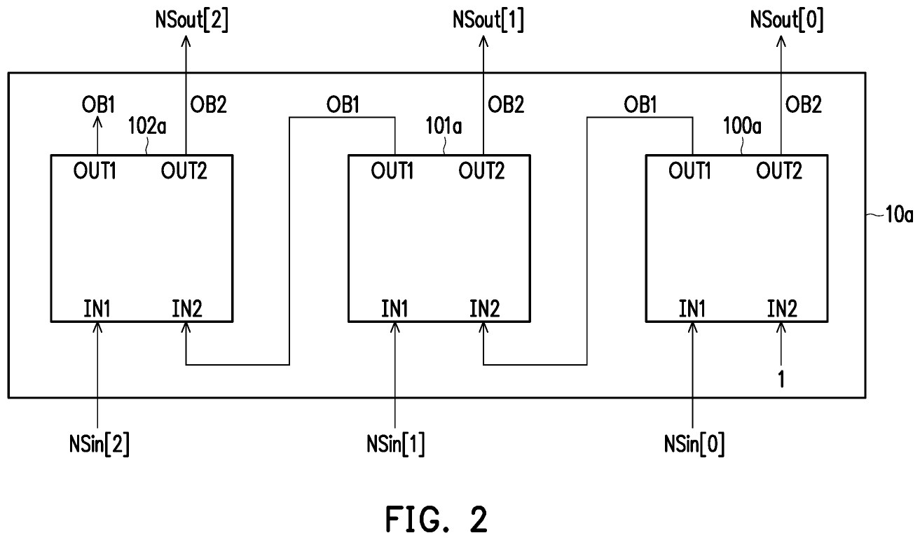

FIG. 2 illustrates a schematic diagram of a numbering circuit 10a according to some embodiments of the present disclosure. The numbering circuit 10a may be applied in the memory system 1 as depicted in FIG. 1 to replace any of the numbering circuits 10-1 to 10-4. The numbering circuit 10a is configured to receive an input number signal NSin to generate an output number signal NSout accordingly. The numbering circuit 10a includes a plurality of calculating circuits 100a-102a coupled in series. The number of the calculating circuits 100a-102a may be altered based on a required bit number of the number signal or the amount of the memory dies in each stack. In the following paragraphs, descriptions will be made for explaining one of the various structures of the numbering circuit 10a configured for processing the three-bit number signal.

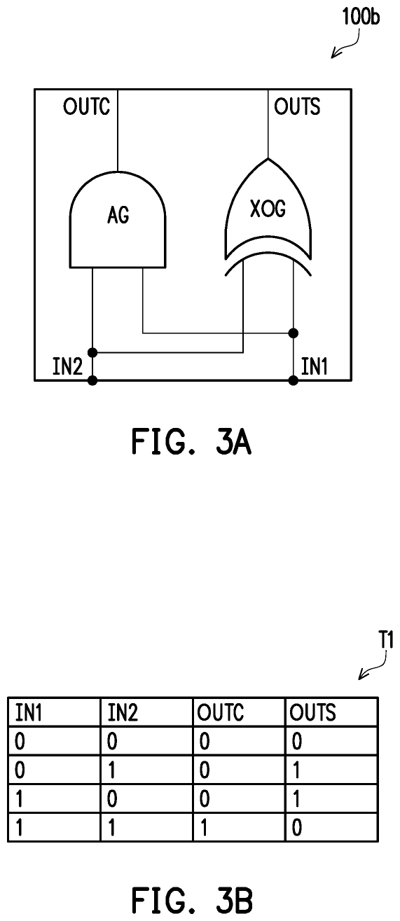

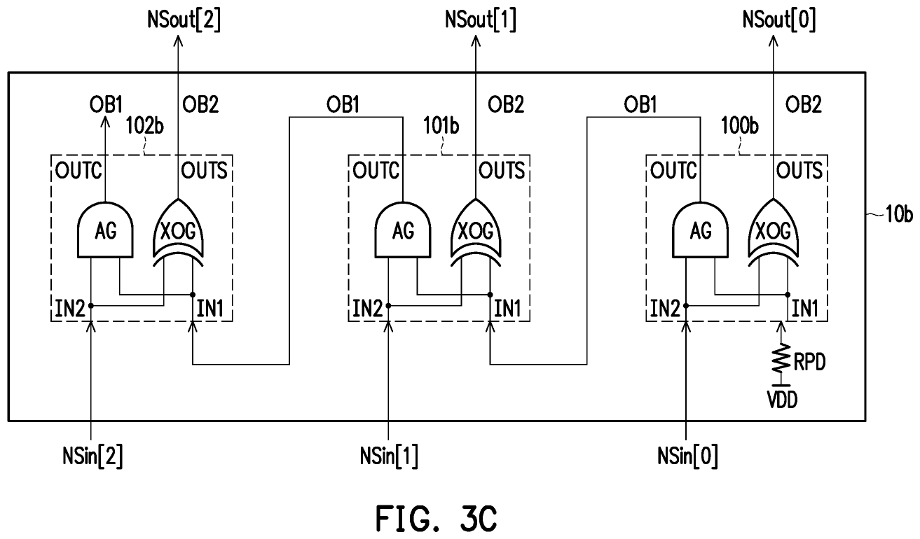

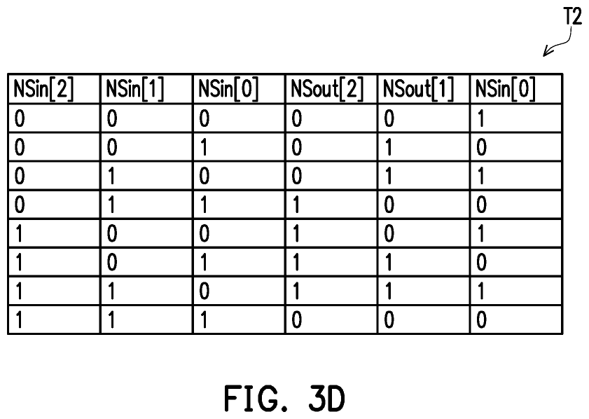

FIG. 3A illustrates a schematic diagram of a calculating circuit 100b according to some embodiments of the present disclosure. The calculating circuit 100b may be applied in the memory system 10a to replace any of calculating circuits 100a-102a in FIG. 2.

Specifically, the calculating circuit 100b includes a first input end IN1, a second input end IN2, a first output end OUTC, and a second output end OUTS. Each of the calculating circuit includes an exclusive-OR (XOR) gate XOG and an AND gate AG. Both of the XOR gate XOG and the AND gate are both coupled to the first input end and the second input end. The XOR gate XOG is configured to receive input bits from the first and second input ends IN1, IN2 to calculate a sum of the two input bits and output the sum to the second output end OUTS. Further, the AND gate AG is configured to receive the two input bits from the first and second input ends IN1, IN2 to calculate a carry of the two input bits, output the carry to the first output end OUTC.

FIG. 3B illustrates a truth table T1 of a calculating circuit 100b in FIG. 3A according to some embodiments of the present disclosure.

In such embodiment, the calculating circuit 100b is functioning as a half adder. The output bits of carry and sum generated by the calculating circuit 100b combined correspond to a value of a summation result of the two received input bits of the calculating circuit 100b. Specifically, the calculating circuit 100b generates the output bit of 1 to the second output end OUTS when the received input bits are 01 or 10, otherwise the calculating circuit generates the output bit of 0 to the second output end OUTS when the received input bits are 00 or 11, Further, the calculating circuit 100b generates the output bit of 1 to the first output end OUTC when the received input bits are 11, and generates the output bit of 0 to the first output end OUTC when the received input bits are 00, 01, or 10. Therefore, a value of the output bits in combination generated by the calculating circuit 100b corresponds to a summation of bit values of the input bits received by the calculating circuit 100b.

FIG. 3C illustrates a numbering circuit 10b according to some embodiments of the present disclosure. The numbering circuit 10b may be applied in the memory system 1 in FIG. 1 to replace any of the numbering circuits 10-1 to 10-4. Specifically, the numbering circuit 10b is configured to calculate a summation of a value of the input number signal NSin with a predetermined difference to generate the output number signal NSout. For example, the predetermined difference may be set as one, and the numbering circuit 10b may increase the value corresponding to the input number signal by one and generate the output number signal corresponding to the location information where the memory die is in the stack. Consequently, the serially coupled numbering circuits 10b may generate the sequentially increased output number signals NSout.

Taking the calculating circuit 101b as an example, the XOR gate XOG receives input bits of the first output bit OB1 from the previous stage calculating circuit 100b and the corresponding bit NSin [1] of the input number signal NSin, to accordingly calculate the second output bit OB2 corresponding to the sum of the two input bits, and taken as the bit NSout [1] of the output number signal NSout. Further, the AND gate AG1 is configured to receive the input bits the first output bit OB1 from the previous stage calculating circuit 100b and the corresponding bit NSin [1], to accordingly calculate the first output bit OB1 corresponding to the carry of the two input bits, and the next stage calculating circuit 102b may take the first output bit OB1 from the current stage calculating circuit 101b as the input. Therefore, as the first output bit OB1 corresponding to the carry is determined by the calculating circuits 100b-102b stage by stage and to the last stage of the calculating circuit 102b, the calculating circuits 100b-102b may be sequentially configured to generate the corresponding bits of the output number signal NSout from the LSB to MSB.

In order for the numbering circuit 10b to calculate the summation of the input number signal NSin and the predetermined difference, a reference voltage VDD is provided to the first input end IN1 of at least one calculating circuit in the serially coupled calculating circuits 100b-102b through a resistor RPD. In this embodiment, the predetermined difference may be set as one, and thus the reference voltage VDD may be provided to the first stage calculating circuit 100b of the serially coupled calculating circuits 100b-102b. The inputted reference voltage VDD may be read as a digital value one by the calculating circuit 100b, thereby a summation of the input bit NSin [0] of the input numbering signal NSin and one is calculated by the calculating circuit 10b to generate the output bits OB2, OB1 respectively corresponding to carry and sum. The output bit OB1 generated by the calculating circuit 100a may be inputted to the calculating circuit 101a for calculating the sum and carry of the next stage. Sequentially, each stage of calculating circuit may be configured to calculate corresponding sum and carry upon receiving the carry from the previous stage calculating circuit. After the last stage calculating circuit 102 completes the calculation, the correct output number signal NSout may be generated by the numbering circuit 10a. However, the predetermine difference is not only limited to one. For example, by providing the reference voltage VDD (i.e., the digital value one) to the first input end IN1 of other calculating circuits, the summation of the input number signal NSin with other values of the predetermined difference may be realized, which are also within the scope of various embodiments of the numbering circuit 10b.

FIG. 3D illustrates a truth table T2 of a numbering circuit 10b in FIG. 3C according to some embodiments of the present disclosure.

In such embodiment, the predetermined difference is one, and the numbering circuit 100b is configured to generate the output number signal NSout by increasing the value of the received input number signal NSin by one. As can be seen in the truth table T2, the generated output number signal NSout is greater than the input number signal NSin by one. Therefore, the desired functions of the numbering circuit 10b is well realized by the structures of the calculating circuit 100b-102b as depicted in FIG. 3C.

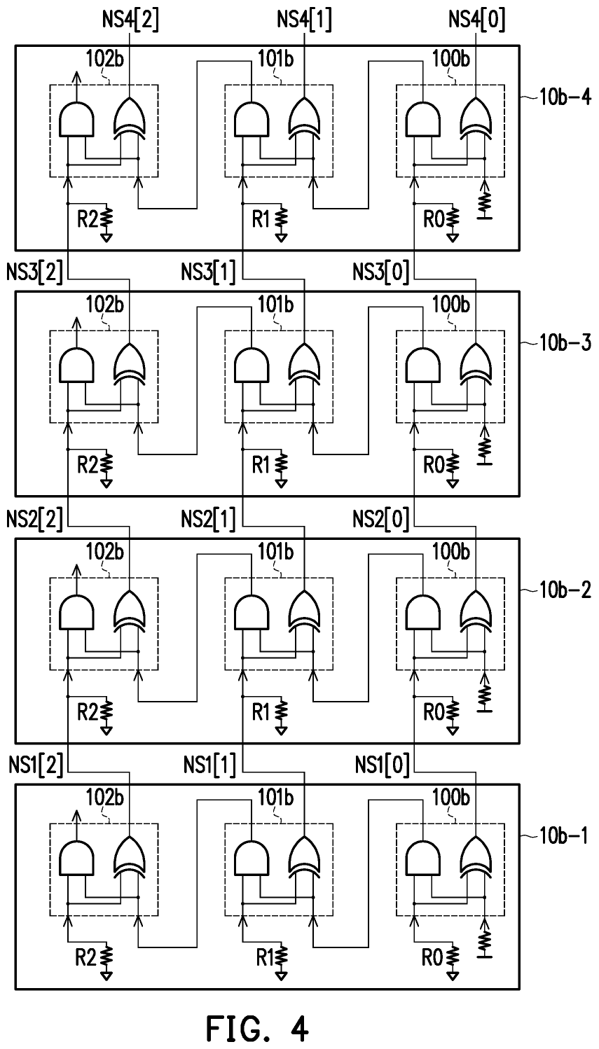

FIG. 4 illustrates a plurality of serially coupled numbering circuits 10b-1 to 10b-4 according to some embodiments of the present disclosure. Each of the numbering circuits 10b-1 to 10b-4 in FIG. 4 is similar to the numbering circuit 10b in FIG. 3C, and thus the symbols for the same components are omitted in FIG. 4 for clarity. The numbering circuits 10b-1 to 10b-4 in FIG. 4 may replace and represent the serially coupled numbering circuits 10-1 to 10-4 in FIG. 1.

Specifically, the numbering circuits 10b-1 to 10b-4 are coupled in series. Each numbering circuit is configured to function as a current stage numbering circuit to receive the input number signal provided from the previous stage numbering circuit and generate the output number signal to the next stage numbering circuit except the first stage numbering circuit 10b-1. For the first stage numbering circuit 10b-1 to properly start counting, a predetermined number signal is provided the first stage numbering circuit 10b-1, and more particularly to the second input ends of the calculating circuits 100b-102b of the first stage numbering circuit 10b-1. In this embodiment, a reference voltage GND is provided to the second input ends of the calculating circuits 100b-102b of the first stage numbering circuit 10b-1 respectively through resistors R0-R2. The reference voltage GND may be read as a digital value 0 by the calculating circuits 100b-102b, so that the first stage numbering circuit 10b-1 may receive the predetermined number signal of 000.

Further, since the predetermined difference is one in this embodiment, each numbering circuit may be configured to increase the value of the received input number signal by one and generate the output number signal. The bits of the number signal generated from the previous stage numbering circuit are provided to the second input ends of the calculating circuits 100b-102b of the current stage numbering circuit. However, since all numbering circuits are designed using the same circuit structure as the first stage numbering circuit, the reference voltage GND is also coupled to the second input ends of the calculating circuits 100b-102b of the current stage numbering circuit, but a driving force of the output number signal is greater than a driving force of the predetermined number signal through properly design to the resistors R0-R2 and the XOR gates XOG, so that the numbering circuit may after the first stage numbering circuit may receive the input number signal provided from the previous stage numbering circuit.

In some embodiments, the serially coupled numbering circuits may be designed to generate the number signals using different counting rules. For example, the numbering circuit may be configured to generate the current stage numbering signal in a descending or in increasing order, or the predetermined difference increased by each numbering circuit may be set to other values rather than one, or the predetermined number signal may be other values rather than zero, which are also within the scope of various embodiments.

In summary, each memory die of the memory system is capable of automatically generating a number corresponding to a level where the memory die is in the stack. The memory dies in the memory system may have the same structure with relatively simple design without additionally providing any initiating values to the first or any numbering circuits therein, Therefore, the memory system may have an easier design complexity.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory system, comprising:
a plurality of memory dies stacked within the memory system, each of the memory dies comprising:
a numbering circuit configured to generate an output number signal according to an input number signal, the numbering circuit comprising:
a plurality of calculating circuits coupled in series, a current stage calculating circuit being configured to receive a first output bit from a previous stage calculating circuit and a corresponding bit of the input number signal to generate the first output bit and a second output bit as a correspond bit of the output number signal.

2. The memory system of claim 1, wherein the numbering circuit is configured to add a value of the input number signal with a predetermined difference to generate the output number signal.

3. The memory system of claim 1, wherein the predetermined difference is one.

4. The memory system of claim 1, wherein calculating circuit comprises a first input end and a second input end, the first input end and the second input end are coupled to respectively receive the first output bit from the previous stage calculating circuit and the corresponding bit of the input number signal.

5. The memory system of claim 4, wherein a plurality of bits of a predetermined number signal are respectively provided to the plurality of second input ends of the plurality of calculating circuits.

6. The memory system of claim 5, wherein a first reference voltage is provided to the plurality of second input ends of the plurality of calculating circuit as the plurality of bits of the predetermined number signal.

7. The memory system of claim 6, wherein a plurality of resistors are coupled respectively between the plurality of second input ends of the plurality of calculating circuits and the first reference voltage.

8. The memory system of claim 6, wherein a driving force of the input number signal to the second input end of each calculating circuit is stronger than a driving force of the first reference voltage to the second input end of the same calculating circuit.

9. The memory system of claim 6, wherein a second reference voltage is provided to the first input end of a first stage calculating circuit coupled at a front most stage of the calculating circuits.

10. The memory system of claim 1, wherein each calculating circuit is a half adder.

11. The memory system of claim 1, wherein each calculating circuit comprises:
an exclusive OR (XOR) gate configured to receive the first output bit from the previous stage calculating circuit and the corresponding bit of the input number signal to generate the second output bit as the corresponding bit of the output number signal; and
an AND gate configured to receive the first output bit from the previous stage calculating circuit and the corresponding bit of the input number signal to generate the first output bit.

12. A memory die, adapted to be stacked within a memory system, the memory die comprising:
a numbering circuit configured to generate an output number signal according to an input number signal, the numbering circuit comprising:
a plurality of calculating circuits coupled in series, a current stage calculating circuit being configured to receive a first output bit from a previous stage calculating circuit and a corresponding bit of the input number signal to generate the first output bit and a second output bit as a correspond bit of the output number signal.

13. The memory die of claim 12, wherein the numbering circuit is configured to add a value of the input number signal with a predetermined difference to generate the output number signal.

14. The memory die of claim 12, wherein the predetermined difference is one.

15. The memory die of claim 12, wherein calculating circuit comprises a first input end and a second input end, the first input end and the second input end are coupled to respectively receive the first output bit from the previous stage calculating circuit and the corresponding bit of the input number signal.

16. The memory die of claim 15, wherein a plurality of bits of a predetermined number signal are respectively provided to the plurality of second input ends of the plurality of calculating circuits.

17. The memory die of claim 16, wherein a first reference voltage is provided to the plurality of second input ends of the plurality of calculating circuit as the plurality of bits of the predetermined number signal.

18. The memory die of claim 17, wherein a plurality of resistors are coupled respectively between the plurality of second input ends of the plurality of calculating circuits and the first reference voltage.

19. The memory die of claim 17, wherein a driving force of the input number signal to the second input end of each calculating circuit is stronger than a driving force of the first reference voltage to the second input end of the same calculating circuit.

20. The memory die of claim 17, wherein a second reference voltage is provided to the first input end of a first stage calculating circuit coupled at a front most stage of the calculating circuits.

21. The memory die of claim 12, wherein each calculating circuit is a half adder.

22. The memory die of claim 12, wherein each calculating circuit comprises:
an exclusive OR (XOR) gate configured to receive the first output bit from the previous stage calculating circuit and the corresponding bit of the input number signal to generate the second output bit as the corresponding bit of the output number signal; and
an AND gate configured to receive the first output bit from the previous stage calculating circuit and the corresponding bit of the input number signal to generate the first output bit.
